(19) United States
(12) Patent Application Publication
(10) Pub. No.: US 2007/0029575 A1
(43) Pub. Date: Feb. 8, 2007

(54) Structure and method of measuring the capacitance

(76) Inventors: Hao Zhang, Shanghai (CN); Yuan-Wei Zheng, Shanghai (CN); Hui-Fang Hsu, Shanghai (CN); Juan-Li Liu, Shanghai (CN)

Correspondence Address: ROSENBERG, KLEIN & LEE, 3458 ELLICOTT CENTER DRIVE-SUITE 101, ELLICOTT CITY, MD, 21043, US

(21) Appl. No.: 11/195,633

(22) Filed: Aug. 3, 2005

(51) Int. Cl. H01L 27/10; H01L 21/82

(52) U.S. Cl. 257/208; 438/128; 257/E27.103

(57) ABSTRACT

The structure and method of measuring the capacitance comprising a first buried doped area and a heavily doped area in a semiconductor substrate. The heavily doped area is parallel to the buried doped area. Several second buried doped areas, the first oxide layers and the second oxide layers are formed in the semiconductor substrate. Any of the second buried doped areas is perpendicular to the first buried doped area. One end of the second buried doped area is connected to the first buried doped area, and another end is connected to the heavily doped area. Any of the first oxide layers is overlaid on the second buried doped area. Any of the second oxide layers is placed between any two first oxide layers, and the thickness of the second oxide layer is thinner than the thickness of the first oxide layer. At least two first and several second polysilicon rows are formed on the semiconductor substrate, and wherein two first polysilicon rows are respectively placed on two sides of the second buried doped areas. Any of the second polysilicon rows is perpendicular to the first polysilicon row therein. One end of each of the second polysilicon rows is not connected to two fist polysilicon rows. The structure of the present invention is applied to obtain the individual capacitance in relation to the word line.

### BACKGROUND OF THE INVENTION

1. Field of the Invention

The present invention relates to a structure and method of measuring the capacitance, and more particularly, to a structure and method of measuring the capacitance in relation to the word line in the Mask ROM process.

2. Description of the Prior Art

When simulating the memory access time, more particularly a high speed Mask ROM, a capacitance in relation to the word line is very importance parameter. For examples, in the Mask ROM process, the oxide layer under the polysilicon wordline has the different thickness. Because the buried N-typed (BN) implant with high dose causes greatly the oxidation, the buried N-typed doped (BN) implant junction further results in complicating the entire Mask ROM process and the operation mode.

As shown in FIG. 1A, which is a cross-sectional view taken form one direction of a Mask Read Only Memory (MROM). A substantially uniformly oxide layer 112 and several conducting gate structures 114 are formed on the semiconductor substrate 110. In the MROM, the conducting gate structures 114 also act as the wordlines. Therefore, a WL-WL coupling capacitance “C1” exists between the conducting gate structures 114. As shown in FIG. 1B, which is a cross-sectional view taken form one direction of a Mask Read Only Memory (MROM). Thickness of the oxide layer on the semiconductor substrate is not the same, having the thin oxide layer 116 and the thick oxide layer 118. The conducting gate structures 114 are covered on the entire oxide layer. The buried N-typed doped area 120 is formed under the thick oxide layer 118. According the above structure, a Word line-thin oxide layer capacitance “C2”, a Word line-thick oxide layer capacitance “C3” are existed.

In view of this, the present invention provides a structure and method of measuring the capacitance to overcome the above mentioned disadvantages, in order to design the correct test key used in the Mask ROM structure.

### SUMMARY OF THE INVENTION

The present invention provides a structure and method of measuring the capacitance to obtain the individual capacitance in relation to the word line, in order to design the correct test key used in the Mask ROM structure.

The present invention also provides a structure and method of measuring the capacitance in relation to the word line, which the individual capacitance in relation to the word line is obtained by applying two layout structures and the different measuring conditions.

According to a preferred embodiment of the present invention, a structure and method of measuring the capacitance are provided. The heavily doped area is parallel to the buried doped area. Several second buried doped areas, the first oxide layers and the second oxide layers are formed in the semiconductor substrate. Any of the second buried doped areas is perpendicular to the first buried doped area. One end of the second buried doped area is connected to the first buried doped area, and another end is connected to the heavily doped area. Any of the first oxide layers is overlaid on the second buried doped area. Any of the second oxide layers is placed between any two first oxide layers, and the thickness of the second oxide layer is thinner than the thickness of the first oxide layer. At least two first and several second polysilicon rows are formed on the semiconductor substrate, and wherein two first polysilicon rows are respectively placed on two sides of the second buried doped areas. Any of the second polysilicon rows is perpendicular to the first polysilicon row therein. One end of each of the second polysilicon rows is not connected to two fist polysilicon rows. The structure of the present invention is applied to obtain the individual capacitance in relation to the word line by using the external voltage or the ground.

These and other objectives of the present invention will become obvious to those of ordinary skill in the art after reading the following detailed description of the preferred embodiment.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate one embodiment of the invention and, together with the description, serve to explain the principles of the invention. In the drawing,

FIG. 1A is a cross-sectional view taken form one direction of a Mask Read Only Memory (MROM);

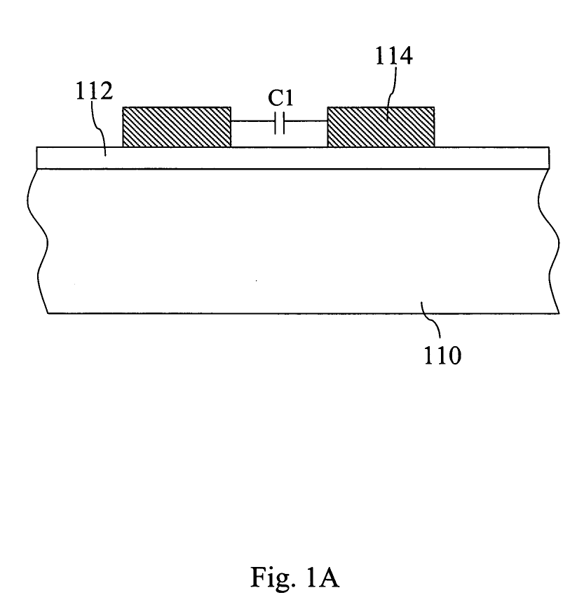

FIG. 1B is a cross-sectional view taken form one direction of a Mask Read Only Memory (MROM);

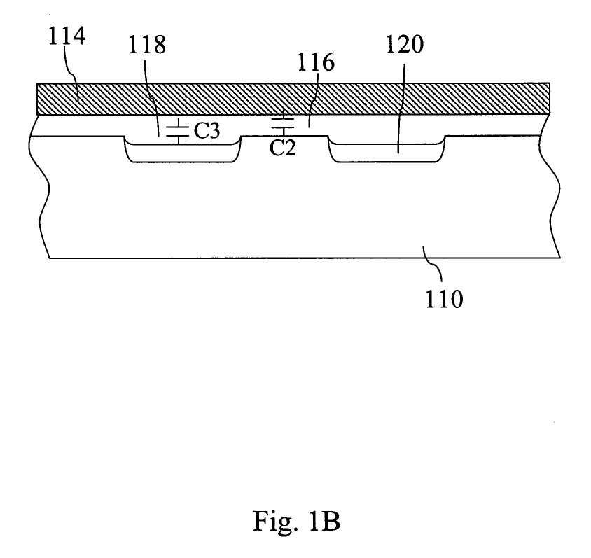

FIG. 2A is a layout diagram of measuring the total capacitance according to one preferred embodiment of this invention;

FIG. 2B is a layout diagram of measuring the parasitic capacitance (Cp) according to one preferred embodiment of this invention; and

FIG. 3 is a layout diagram of measuring the capacitance in relation to word line according to another preferred embodiment of this invention.

### DETAILED DESCRIPTION OF THE PREFERRED EMBODIMENTS

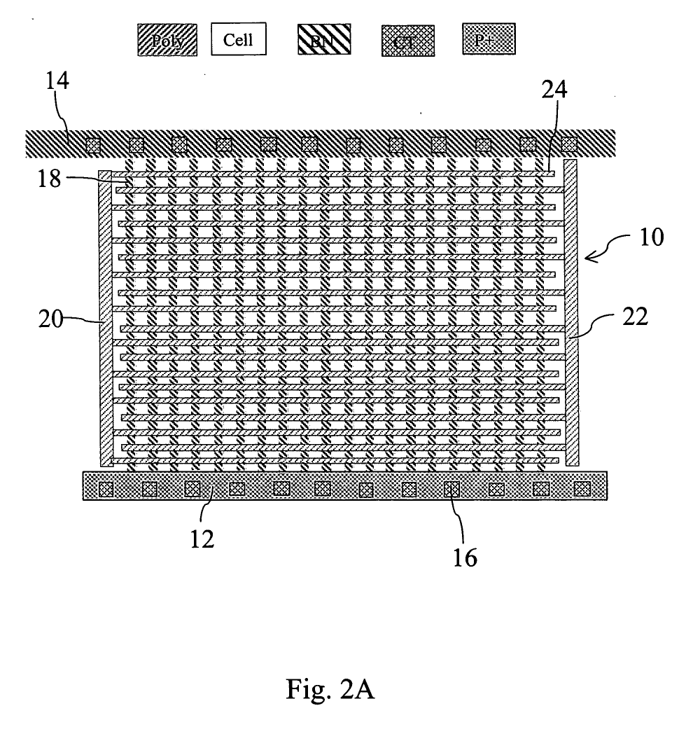

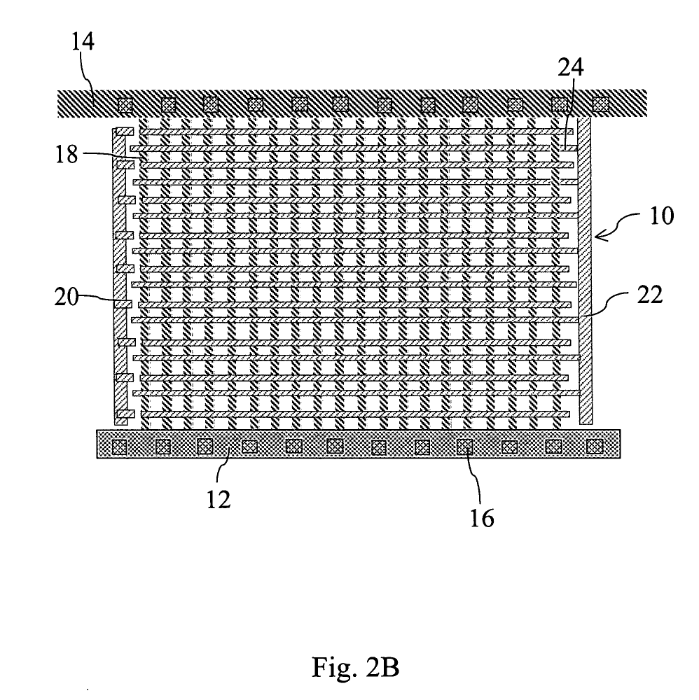

As shown in FIG. 2A, which is a layout diagram of measuring the total capacitance according to this invention. A semiconductor substrate 10 comprises two parallel doped area rows, one is heavily doped P-typed area 12, and another is buried N-typed doped area 14. The heavily doped P-typed area 12 and the buried N-typed doped area 14 have several contacting contacts 16 thereon. Several buried N-typed areas 18, which are perpendicular to the heavily doped P-typed area 12 and the buried N-typed doped area 14 and are connected each other, are formed between the heavily doped P-typed area 12 and the buried N-typed doped area 14 in the semiconductor substrate 10. The buried N-typed rows 18 are separately parallel each other.

Two polysilicon rows 20 and 22 are parallel with the buried N-typed doped rows 18 on the semiconductor substrate 10. The lengths of the polysilicon rows 20 and 22 are not extended to the top of the heavily doped P-typed area 12 and the buried N-typed doped area 14. The polysilicon rows 20 and 22 are respectively placed on two sides of the buried N-typed doped rows 18. Several polysilicon rows 24, which are parallel with the heavily doped P-typed area 12 and the buried N-typed doped area 14, are formed between the polysilicon rows 20 and 22. One end of any of the polysilicon rows is extended to the polysilicon row 20 or 22. Another end of any of the polysilicon rows is not connected to the polysilicon row 20 or 22. As shown in FIG. 2A, One ends of odd lines of the polysilicon rows 24 are extended to the polysilicon row 20, and another ends are not connected to the polysilicon row 22. One ends of even lines of the polysilicon rows 24 are extended to the polysilicon row 22, and another ends are not connected to the polysilicon row 20.

One ends of the separated polysilicon rows 24 are extended to one of the polysilicon rows 20 and 22, and the polysilicon rows 24 and the buried N-typed doped rows 18 are perpendicular to each other. As the same as shown in 1B, the thick oxide layers (not shown in the drawings) are formed between the polysilicon rows 24 and the buried N-typed doped rows 18, thereby overlapping with the buried N-typed doped rows 18. The thin oxide layers (not shown in the drawing) are formed between the polysilicon rows 24 and the semiconductor substrate 10, and any of the thin oxide layers is placed between two thick oxide layers.

In order to apply the present invention, an external voltage Vdd is applied on the polysilicon row 20 and the polysilicon row 22, the heavily doped P-typed area 12 (or the semiconductor substrate 10), and the buried N-typed doped area 14 are the ground, a total capacitance “Ca” is measured. The total capacitance “Ca” comprises a Word line-Word line coupling capacitance “C1”, a Word line-thin oxide layer capacitance “C2”, a Word line-thick oxide layer capacitance “C3”, and a parasitic capacitance (Cp). According to the above layout and measuring method, a total capacitance “Ca” is obtained.

As shown in FIG. 2B, which is a layout diagram of measuring the parasitic capacitance (Cp) according to the present invention. Compared with FIG. 2A, one end of odd lines of the polysilicon rows 24 are not extended to the polysilicon rows 20. Therefore, two ends of odd lines of the polysilicon rows 24 are not extended to the polysilicon rows 20 and 24. The measuring condition of FIG. 2B is the same as Fig. According to the above mention, this layout is applied to obtain a parasitic capacitance (Cp). The total capacitance “Ca” of FIG. 2A minus the parasitic capacitance (Cp) leaves a total capacitance “Cb”, comprising a Word line-Word line coupling capacitance “C1”, a Word line-thin oxide layer capacitance “C2”, and a Word line-thick oxide layer capacitance “C3”.

The layout of FIG. 2 is applied with the different measuring condition, thereby obtaining the others capacitances. In this embodiment, when an external voltage Vdd is applied on the polysilicon row 22, and the heavily doped P-typed area 23 (or the semiconductor substrate 10) and the buried N-typed doped area 14 are the ground, the total capacitance “Cc”, comprising a Word line-thin oxide layer capacitance “C2” and a Word line-thick oxide layer capacitance “C3”, is obtained. The total capacitance “Cb” minus the total capacitance “Cc” leaves a Word line-Word line coupling capacitance “C1”.

The ratio of the Word line-thin oxide layer capacitance “C2” and the Word line-thick oxide layer capacitance “C3” in the layout structure of the present invention is changed to obtain the different total capacitance “Cc”. By using at two different total capacitances “Cc”, the individual Word line-thin oxide layer capacitance “C2” and the Word line-thick oxide layer capacitance “C3” are obtained. According the present invention, all individual capacitances in relation to the word lines are measured.

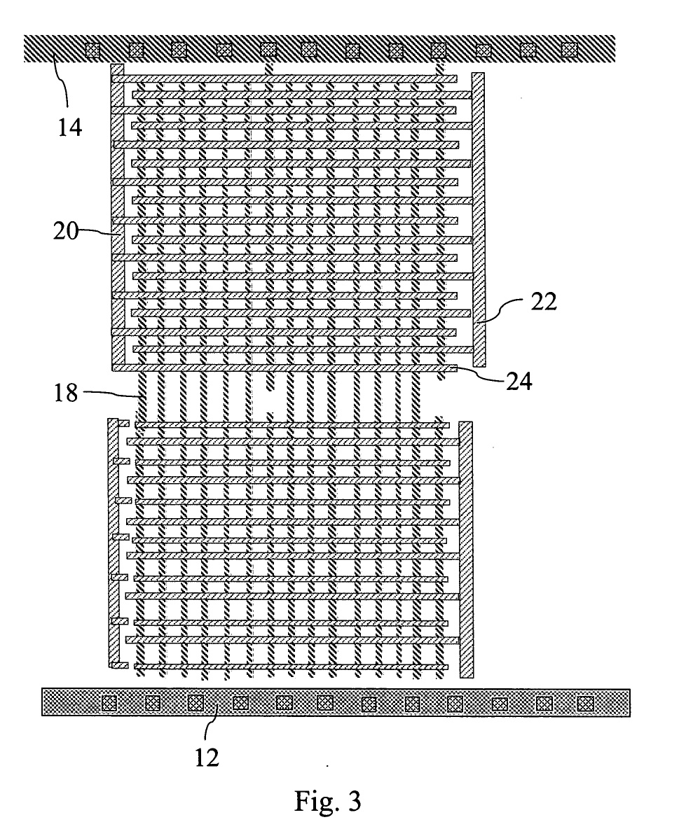

FIG. 3 is a layout diagram of measuring the capacitance in relation to word line according to another preferred embodiment of this invention. Selectively, the layout of FIG. 2A and the layout of FIG. 2B are combined to obtain the individual capacitance in relation to the word lines. In this embodiment, all buried N-typed area rows 18 of FIG. 2A and FIG. 2B are connected. One of the layout does not need the heavily doped P-typed area 12, and another of the layout does not need the buried N-typed doped area 14. Therefore, all buried N-typed doped area rows 18 of FIG. 2A and FIG. 2B are connected. All capacitances in relation to the word lines are measured by using the above measuring conditions.

The embodiment above is only intended to illustrate the present invention; it does not, however, to limit the present invention to the specific embodiment. Accordingly, various modifications and changes may be made without departing from the spirit and scope of the present invention as described in the following claims.

What is claimed is:

1. A structure of measuring a capacitance, comprising:
a semiconductor substrate:
a first striped buried doped area in the semiconductor substrate;
a striped heavily doped area in the semiconductor area, and wherein the striped heavily doped area is parallel with the first striped buried doped area;
a plurality of second striped buried doped areas in the semiconductor substrate, and wherein any of the second striped buried doped areas is perpendicular to the first striped buried doped area, and one end of any of the second striped buried doped areas is connected to the first striped buried doped area, and another end of any of the second striped buried doped areas is connected to the striped heavily doped area;
a plurality of first oxide layers in the semiconductor substrate, and wherein any of the first oxide layers is overlaid on any of the second striped buried doped areas;
a plurality of second oxide layers in the semiconductor substrate, and wherein any of the second oxide layers is placed between any two of the first oxide layers, and the thickness of each second oxide layer is thinner than the thickness of any of the first oxide layers;
at least two striped first polysilicon rows on the semiconductor substrate, and wherein the two striped first polysilicon rows are respectively placed on two sides of a plurality of the second striped buried doped areas; and
a plurality of striped second polysilicon rows on the semiconductor substrate, and wherein each striped second polysilicon row is perpendicular on the two striped first polysilicon rows, and one end of each striped second polysilicon row is not connected to the two striped first polysilicon rows.

2. The structure of measuring the capacitance of claim 1, comprising a plurality of conducting contacts on the first striped buried doped area having an electrical connection with the first striped buried doped area.

3. The structure of measuring the capacitance of claim 1, comprising a plurality of conducting contacts on the striped heavily doped area having an electrical connection with the striped heavily doped area.

4. The structure of measuring the capacitance of claim 3, wherein a plurality of the second striped buried doped areas are separated each other.

5. The structure of measuring the capacitance of claim 1, wherein one of the two striped first polysilicon rows is connected to an external voltage, and another of two striped first polysilicon rows is a ground.

6. The structure of measuring the capacitance of claim 1 or 5, wherein another end of one of any two adjacent striped second polysilicon rows is connected to one of the two striped first polysilicon rows.

7. The structure of measuring the capacitance of claim 6, wherein another end of one of the two adjacent striped second polysilicon rows is connected to another of the two striped first polysilicon rows.

8. The structure of measuring the capacitance of claim 6, wherein another end of one of the two adjacent striped second polysilicon rows is not connected to one of the two striped first polysilicon rows.

9. The structure of measuring the capacitance of claim 7, using for measuring a parasitic capacitance value.

10. The structure of measuring the capacitance of claim 1 or 5, wherein the striped heavily doped area and the striped buried doped area are the ground.

11. The structure of measuring the capacitance of claim 1, wherein the two striped first polysilicon rows are connected to an external voltage.

12. The structure of measuring the capacitance of claim 1 or 11, wherein another end of one of any two adjacent striped second polysilicon rows is connected to one of the two striped first polysilicon rows.

13. The structure of measuring the capacitance of claim 12, wherein another end of another of the two adjacent striped second polysilicon rows is not connected to another of the two striped first polysilicon rows.

14. A method of forming and measuring a capacitance structure in relation to word line, comprising:
providing a semiconductor substrate;
forming a first buried doped area in the semiconductor substrate;
forming a striped heavily doped area in the semiconductor substrate, and wherein the striped heavily doped area is parallel with the first striped buried doped area;
forming a plurality of second striped doped areas in the semiconductor substrate, and wherein any of the second striped buried doped areas is perpendicular to the first striped buried doped area, and one end of any of the second striped buried doped areas is connected to the first striped buried doped area, and another end of any of the second striped buried doped areas is connected to the striped heavily doped area;
forming a plurality of first oxide layers in the semiconductor substrate, and wherein any of the first oxide layers is overlaid on any of the second striped buried doped areas;
forming a plurality of second oxide layers in the semiconductor substrate, and wherein any of the second oxide layers is placed between any two of the first oxide layers, and the thickness of each second oxide layer is thinner than the thickness of any of the first oxide layers;
forming a plurality of second oxide layers in the semiconductor substrate, and wherein any of the second oxide layers is placed between any two of the first oxide layers, and the thickness of each second oxide layer is thinner than the thickness of any of the first oxide layers;
forming at least two striped first polysilicon rows on the semiconductor substrate, and wherein the two striped first polysilicon rows are respectively placed on two sides of a plurality of the second striped buried doped areas; and
forming a plurality of striped second polysilicon rows on the semiconductor substrate, and wherein each striped second polysilicon row is perpendicular on the two striped first polysilicon rows, and one end of each striped second polysilicon row is not connected to the two striped first polysilicon rows.

15. The method of forming and measuring a capacitance structure in relation to word line of claim 14, wherein forming another end of one of any two adjacent striped second polysilicon rows comprises connecting to one of the two striped first polysilicon rows.

16. The method of forming and measuring a capacitance structure in relation to word line of claim 15, wherein forming another end of another of the two adjacent striped second polysilicon rows comprises connecting to another of the two striped first polysilicon rows.

17. The method of forming and measuring a capacitance structure in relation to word line of claim 14 or 15, wherein forming one of the two striped first polysilicon rows comprises connecting to an external voltage, and another of two striped first polysilicon rows is a ground.

18. The method of forming and measuring a capacitance structure in relation to word line of claim 14 or 15, wherein the striped heavily doped area and the striped buried doped area are the ground.

19. The method of forming and measuring a capacitance structure in relation to word line of claim 15, wherein forming another end of another of the two adjacent striped second polysilicon rows is not connected to another of the two striped first polysilicon rows.

20. The method of forming and measuring a capacitance structure in relation to word line of claim 14 or 19, wherein forming one of the two striped first polysilicon rows is connected to an external voltage, and another end of the two striped first polysilicon rows is a ground.

21. The method of forming and measuring a capacitance structure in relation to word line of claim 14 or 19, wherein forming the two striped first polysilicon rows comprises connecting to at least one external voltage.

22. The method of forming and measuring a capacitance structure in relation to word line of claim 14 or 19, wherein the striped heavily doped area and the striped buried doped area are the ground.
